(19) United States
(12) Patent Application Publication
(10) Pub. No.: US 2009/0321784 A1
(43) Pub. Date: Dec. 31, 2009

(54) Semiconductor Device and Method of Forming Lateral Power MOSFET with Integrated Schottky Diode on Monolithic Substrate

(75) Inventors: Samuel J. Anderson, Tempe, AZ (US); David N. Okada, Chandler, AZ (US); David A. Shumate, Phoenix, AZ (US); Gary Dashney, Phoenix, AZ (US)

Correspondence Address: Robert D. Atkins, 605 W. Knox Road, Suite 104, Tempe, AZ, 85284, US

(73) Assignee: GREAT WALL SEMICONDUCTOR CORPORATION, Tempe, AZ (US)

(21) Appl. No.: 12/490,112

(22) Filed: Jun. 23, 2009

Related U.S. Application Data
(60) Provisional application No. 61/075,662, filed on Jun. 25, 2008.

(51) Int. Cl. H01L 25/07; H01L 21/328

(52) U.S. Cl. 257/140; 438/135; 438/237; 257/341; 257/E25.014; 257/E21.35

(57) ABSTRACT

A monolithic semiconductor device has an insulating layer formed over a first substrate. A second substrate is disposed over the first insulating layer. A power MOSFET with body diode is formed over the second substrate. A Schottky diode is formed over the second substrate in proximity to the MOSFET. An insulation trench is formed within the second substrate between the MOSFET and Schottky diode. The isolation trench surrounds the MOSFET and first Schottky diode. A first electrical connection is formed between a source of the MOSFET and an anode of the Schottky diode. A second electrical connection is formed between a drain of the MOSFET and a cathode of the Schottky diode. The Schottky diode reduces charge build-up within the body diode and reverse recovery time of the first power MOSFET. The power MOSFET and integrated Schottky can be used in power conversion or audio amplifier circuit.

### CLAIM TO DOMESTIC PRIORITY

The present non-provisional patent application claims priority to provisional application Ser. No. 61/075,662, entitled “Lateral Power MOSFET with Integrated Schottky Diode,” filed on Jun. 25, 2008.

### FIELD OF THE INVENTION

The present invention relates in general to electronic circuits and semiconductor devices and, more particularly, to a semiconductor device and method of forming a lateral power MOSFET with integrated Schottky diode on a monolithic substrate.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. Back-end manufacturing involves singulating individual die from the finished wafer and packaging the die to provide structural support and environmental isolation.

MOSFETs (metal-oxide-semiconductor field-effect transistors) are commonly used in electronic circuits, such as communication systems and power converters. Power MOSFETs are particularly useful as electric switches to enable and disable the conduction of relatively large currents. In MOSFETs, current flows between conduction terminals, e.g., from the source to the drain. The static drain-source on-resistance (RDSON) should be minimized to avoid power loss and heat dissipation. The power MOSFET switch is typically contained within a monolithic package for ease of integration and system design.

In one application, power MOSFETs are used in switching power conversion systems and class D audio amplifiers. During operation of the power MOSFET, the body diode of the MOSFET is alternately biased between a conduction state and blocking state. During forward bias of the body diode, the MOSFET conducts and electric charge is stored in neutral regions located adjacent to the PN junction of the body diode. Before returning to the blocking state, the charge must be extracted and neutralized during a reverse recovery period.

The extraction and neutralization of the body diode charge results in power loss which lowers the power conversion efficiency of the power MOSFET. For efficient operation, the circuit must minimize both the amount of accumulated reverse recovery charge (Qᵣᵣ) and the characteristic reverse recovery time (tᵣᵣ) necessary to extract or neutralize the charge.

FIG. 1 illustrates a cross-sectional view of a conventional lateral power MOSFET 10 that includes a body diode. Substrate 12 is made of P-type semiconductor material and provides structural support to the device. The following regions and layers are formed over substrate 12 using semiconductor manufacturing processes, such as layering, patterning, doping, and heat treatment. In the layering process, materials are grown or deposited on the substrate by techniques involving thermal oxidation, nitridation, chemical vapor deposition, evaporation, and sputtering. Patterning involves the use of photolithography to mask areas of the surface and etch away undesired material. The doping process injects concentrations of dopant material by thermal diffusion or ion implantation.

Using the above semiconductor manufacturing processes, a P− well region 14 is formed on substrate 12. A body region 16 made with P-type material is formed over P− well region 14. P+ body 18 and N+ source region 20 are formed in P-type body region 16. Terminal 22 is a conductive material connected to N+ source region 20 to provide the source terminal of power MOSFET 10. An N+ drain region 24 is formed in P− well region 14 and includes a lightly doped drain (LDD) or drift region. Terminal 25 is a conductive material connected to N+ drain region 24 to provide the drain terminal of power MOSFET 10. Oxide layer 26 is formed over N+ source region 20, P-type body region 16, and N+ drain region 24. Gate region 28 is formed over oxide layer 26.

P-type regions 12-18, in combination with N+ region 24, form a body diode of MOSFET 10 as indicated by diode symbol 30. During operation of the MOSFET, the forward biased body diode 30 stores excess minority carrier charge in region 31. As a result of the charge build-up, when the circuit commutates the body diode, the stored charge must be extracted or neutralized before the diode can achieve its “off state.” The excess minority carriers must diffuse to the surface of the MOSFET to be extracted or recombine in the substrate to be neutralized. The depth of the stored minority carrier charge and long minority carrier lifetime of the substrate increases both tᵣᵣ and Qᵣᵣ, which increases power loss and lowers the efficiency of power MOSFET 10.

FIG. 2 illustrates a conventional power conversion circuit implemented by synchronous buck regulator 32 using MOSFETs each having a body diode. In one example, regulator circuit 32 operates as a step-down voltage regulator circuit. The regulator circuit includes two MOSFETs and requires two relatively short “dead times” in which to switch conduction between the first and second MOSFETs. During the dead times, both MOSFETs are turned off to avoid short-circuiting the power supply.

In regulator circuit 32, a voltage is applied between terminal 34 which is connected to the drain terminal of MOSFET 35 and ground or low voltage terminal 43. The gate of MOSFET 35 is connected to an output of pulse-width modulation control circuit (PWM) 36. PWM 36 includes a switching regulator to control the operation of MOSFETs 35 and 37 which in turn determine when power is supplied to load 41 by the voltage at terminal 34 or inductor 38. The source terminal of MOSFET 35 is connected to a first terminal of inductor 38 and the drain terminal of MOSFET 37. The gate terminal of MOSFET 37 is connected to an output of PWM 36. A second terminal of inductor 38 is connected to a first terminal of capacitor 40 and to output terminal 42. A second terminal of capacitor 40 is connected to ground or low voltage terminal 43.

During a first phase of operation of regulator circuit 32, a voltage is supplied to the gate terminal of MOSFET 35, to activate. The MOSFET is turned on and energy flows from the drain terminal of MOSFET 35 to its source terminal. MOSFET 37 is turned off. With MOSFET 35 turned on and MOSFET 37 turned off, energy is delivered from terminal 34, through inductor 38 to output terminal 42 and load 41. During this phase of operation, energy is accumulated within inductor 38.

In a second phase of operation, both MOSFETs 35 and 37 are turned off. The second phase is known as dead time and is the period of time during which regulator circuit 32 switches from the voltage at terminal 34 to inductor 38 as the energy supply for load 41. The voltage at the drain terminal of MOSFET 37 swings negative below the voltage at the source terminal of MOSFET 37 until the body diode of MOSFET 37 is forward biased. Current flows from the source to the drain of MOSFET 37 through inductor 38 to load 41. When the body diode of MOSFET 37 is forward biased, it stores charge in the body diode region that needs to be removed when the diode is reversed biased.

In a third phase of operation, MOSFET 35 remains switched off, and a voltage is supplied to the gate terminal of MOSFET 37 to activate the device. With MOSFET 37 turned on, the current stored within inductor 38 flows through MOSFET 37 and supplies energy to load 41.

In a fourth phase of operation, MOSFET 37 is turned off by reducing the gate to source voltage of MOSFET 37 to a level below its threshold. During this time, the body diode of MOSFET 37 is forward biased and conducts current from the source to drain of MOSFET 37 through inductor 38 to load 41. The stored charge is accumulated in the body diode during forward bias. PWM 36 supplies a voltage to the gate to turn on MOSFET 35. The current through MOSFET 35 ramps up and the current through MOSFET 37 ramps down. The body diode of MOSFET 37 becomes reverse biased. Eventually, all of the current supplied to the inductor 38 is supplied from MOSFET 35. Additional current is supplied from MOSFET 35 to remove the stored charge in the body diode of MOSFET 37. Current flows from MOSFET 35 to MOSFET 37 to remove the excess stored charge in the body diode of MOSFET 37. The extra current flow to MOSFET 37 during this phase results in additional power loss for the converter circuit. The greater the max reverse recovery current (I_{RM}), tᵣᵣ, and stored charge for the body diode of MOSFET 37, the greater the power loss.

FIG. 3 illustrates a test circuit for measuring the duration of the body diode reverse recovery process. In the test circuit, PWM 44 is coupled to the gate terminal of MOSFET 46 via adjustable resistor 45. PWM 44 controls the operation of MOSFET 46 and includes logic for determining when to apply a voltage to the gate terminal of MOSFET 46. An anode of body diode 47 is coupled to the source terminal of MOSFET 46, and a cathode of body diode 47 is coupled to the drain terminal of MOSFET 46. Both the anode of body diode 47 and the source of MOSFET 46 are coupled to ground or low-voltage terminal 53. The drain of MOSFET 46 is coupled to a first terminal of variable inductor 50, source terminal of MOSFET 48, and anode of body diode 49. The gate terminal of MOSFET 48 is coupled to the source terminal of MOSFET 48 to bias MOSFET 48 into an off (or non-conducting) state. The drain of MOSFET 48 is coupled to the cathode of body diode 49, second terminal of inductor 50, and voltage source 51. When operating the test circuit, voltage is applied from PWM 44 to a level greater than the threshold voltage of MOSFET 46. The applied voltage turns on MOSFET 46 and current flows from voltage source 51 through inductor 50 and MOSFET 46 to ground terminal 53. The current flow stores energy in inductor 50. PWM 44 turns off MOSFET 46 and current continues to flow through inductor 50 and forward biased body diode 49. Current flows in the upper current loop of body diode 49 and inductor 50. PWM 44 turns on MOSFET 46 again and conducts current. By controlling the input to MOSFET 46, body diode 49 is commutated such that the forward current through the diode is reduced at a specified rate of change (di/dt).

FIG. 4 illustrates an example output of the test circuit of FIG. 3 showing current flow through body diode 49 as diode current decreases over time. The diode current is initially positive, but is decreased and eventually becomes negative. In the forward conduction zone, body diode 49 is conductive. As the diode current becomes negative, shown as point 59, body diode 49 continues conducting. At point 59, an ideal diode would stop conducting electricity and show an output current value of 0 A. However, body diode 49 continues to conduct for a period of time shown as tᵣᵣ. The duration of tᵣᵣ is determined by Qᵣᵣ less the amount of charge built-up within body diode 49. Because it takes an extended period of time for body diode 49 to stop conducting after becoming reverse biased, the switching process for conventional power MOSFET converter systems is inefficient. In one example test, the reverse recovery time of the circuit is approximately 220 ns. In the example, the combination of a large I_{RM} of approximately 6 amperes (A) and a relatively large tᵣᵣ results in a large Qᵣᵣ less the amount of charge stored within the body diode. As the amount of stored charge increases, the efficiency of the device is decreased and power loss is increased.

### SUMMARY OF THE INVENTION

A need exists to minimize the amount of charge build-up within the body diode and the amount of time necessary to remove the build-up charge in order to increase the efficiency of the MOSFET. Accordingly, in one embodiment, the present invention is a monolithic semiconductor device comprising a first substrate and insulating layer formed over the first substrate. A second substrate is disposed over the insulating layer. A power MOSFET with body diode is formed over the second substrate. A first Schottky diode is formed over the second substrate in proximity to the power MOSFET. An insulation trench is formed within the second substrate between the power MOSFET and first Schottky diode. A first electrical connection is formed between a source of the power MOSFET and anode of the first Schottky diode. A second electrical connection is formed between a drain of the power MOSFET and cathode of the first Schottky diode.

In another embodiment, the present invention is a monolithic semiconductor device comprising a first substrate and first power MOSFET with body diode formed over the first substrate. A first Schottky diode is formed over the first substrate in proximity to the first power MOSFET. A first electrical connection is formed between a source of the first power MOSFET and anode of the first Schottky diode. A second electrical connection is formed between a drain of the first power MOSFET and a cathode of the first Schottky diode.

In another embodiment, the present invention is a semiconductor device comprising an electronic circuit and switching device operating in response to the electronic circuit. The switching device includes a substrate and power MOSFET with body diode formed over the substrate. The switching device further includes a Schottky diode formed over the substrate in proximity to the power MOSFET, first electrical connection formed between a source of the power MOSFET and anode of the Schottky diode, and second electrical connection formed between a drain of the power MOSFET and cathode of the Schottky diode.

In another embodiment, the present invention is a method of making a monolithic semiconductor device comprising the steps of providing a first substrate, forming a first power MOSFET with body diode over the first substrate, forming a first Schottky diode over the first substrate in proximity to the first power MOSFET, forming a first electrical connection between a source of the first power MOSFET and anode of the first Schottky diode, and forming a second electrical connection between a drain of the first power MOSFET and cathode of the first Schottky diode.

### BRIEF DESCRIPTION OF THE DRAWINGS

FIG. 1 illustrates a cross-sectional view of a conventional lateral MOSFET and body diode;

FIG. 2 is an equivalent circuit for a conventional synchronous buck power converter circuit with MOSFETs having a body diode;

FIG. 3 is an equivalent circuit for generating MOSFET body diode reverse recovery measurements having an energy source and the MOSFET with body diode;

FIG. 4 is a chart showing a typical reverse recovery waveform of a body diode of a MOSFET generated by the equivalent circuit of FIG. 3;

FIG. 5 is an equivalent circuit for a regulator circuit with a Schottky diode for minimizing the reverse recovery time of the body diode of the MOSFET;

FIG. 6 is a chart showing the typical reverse recovery waveform for a lateral power MOSFET having a Schottky diode as implemented in FIG. 5;

FIG. 7 illustrates a cross-sectional representation of a lateral power MOSFET formed over a semiconductor substrate;

FIG. 8 illustrates a cross-sectional representation of a Schottky diode formed over the semiconductor substrate;

FIGS. 9A-9F illustrate a method of manufacturing a lateral power MOSFET with an integrated Schottky diode on a monolithic substrate;

FIG. 10 illustrates a cross-sectional view of a lateral power MOSFET with an integrated Schottky diode and including etched passivation for a wirebond interconnect;

FIG. 11 illustrates the lateral power MOSFET with integrated Schottky diode and solder bump interconnection;

FIG. 12 illustrates a circuit layout for a dual monolithic lateral power MOSFET with integrated Schottky diode structure;

FIG. 13 illustrates an example configuration of dual monolithic SOI lateral MOSFETs with integrated Schottky diodes showing example device interconnection terminals;

FIG. 14 illustrates a top view of a substrate including dual monolithic lateral MOSFETs with integrated Schottky diodes configured for wire bond interconnection;

FIG. 15 illustrates a top view of a substrate including dual monolithic lateral MOSFETs with integrated Schottky diodes configured for solder bump interconnection;

FIGS. 16A-16B illustrate topological arrangements for lateral power MOSFETs with integrated Schottky diodes; and

FIGS. 17A-17B illustrate half and full-bridge audio amplifiers implemented using lateral power MOSFETs with integrated Schottky diodes.

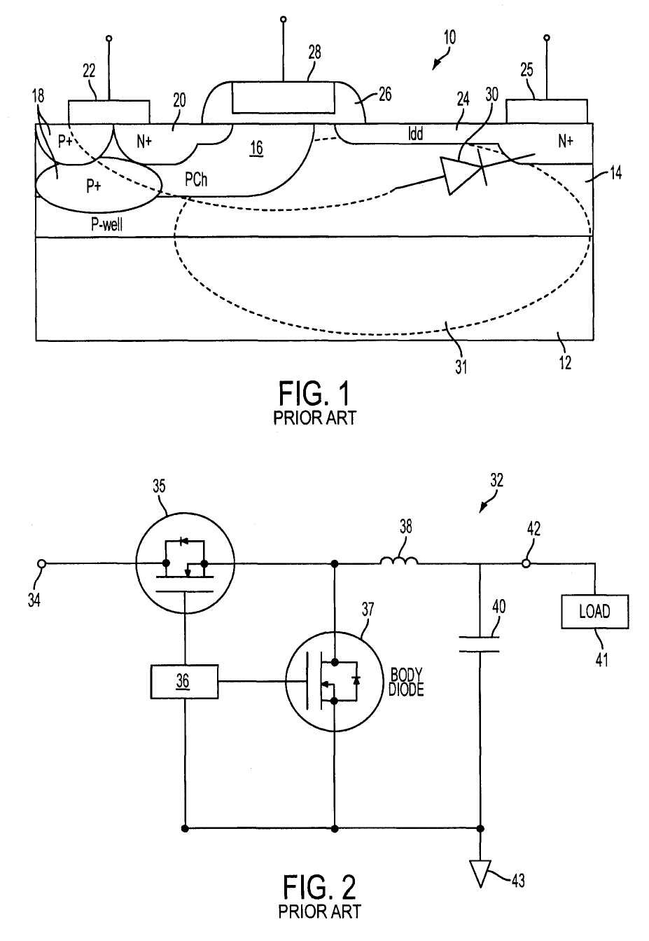

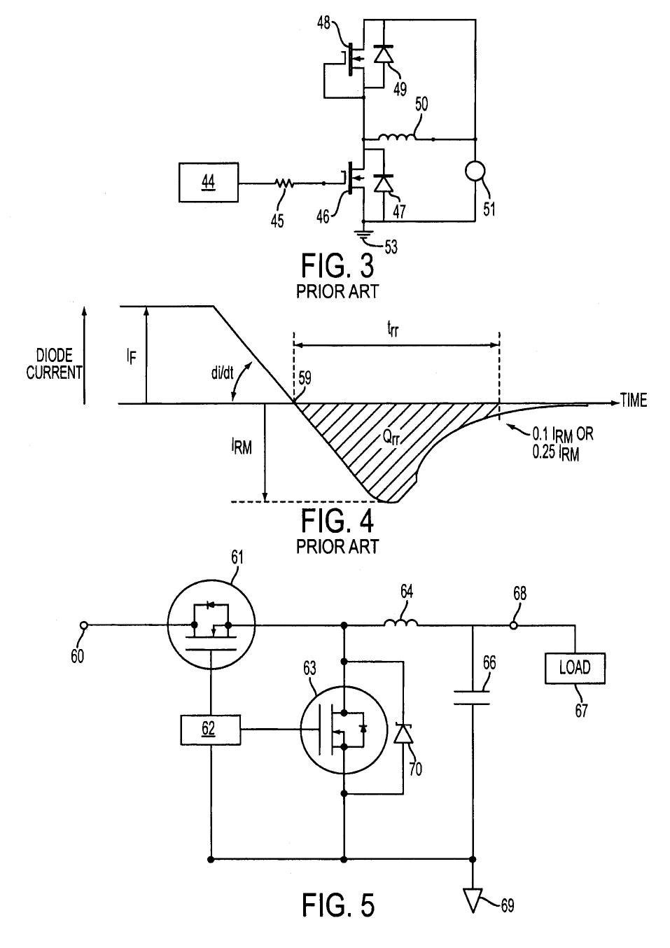

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

Referring to FIG. 5, a regulator circuit is shown with a Schottky diode for minimizing charge build-up within the body diode and reverse recovery losses. The Schottky diode is characterized by a low forward voltage drop and fast switching time. In the regulator circuit, a voltage is applied at terminal 60 which is connected to the drain terminal of MOSFET 61. The gate of MOSFET 61 is connected to a first output of PWM 62. PWM 62 controls the operation of MOSFETs 61 and 63 and includes logic for determining whether power should be supplied by the voltage source at terminal 60 or inductor 64. The source terminal of MOSFET 61 is connected to a first terminal of inductor 64 and the drain terminal of MOSFET 63. Both MOSFETs 61 and 63 include a body diode formed within the substrate of the MOSFETs. The gate terminal of MOSFET 63 is connected to a second output of PWM 62. A second terminal of inductor 64 is connected to a first terminal of capacitor 66 and to output terminal 68 and load 67. Schottky diode 70 is connected between the source and drain terminals of MOSFET 63. A second terminal of capacitor 66 is connected to ground terminal 69.

Schottky diode 70 minimizes the reverse recovery losses associated with the build-up of minority carrier charge within the body diode of MOSFET 63. Schottky diode 70 has a lower forward voltage drop than the PN-junction body diode of MOSFET 63. As a result, the current normally carried by the body diode of MOSFET 63 flows primarily through Schottky diode 70 minimizing the amount of charge build-up within the body diode of MOSFET 63. For this circuit configuration, tᵣᵣ is further minimized due to the quicker reverse recovery of Schottky diode 70. In some cases, the tᵣᵣ with Schottky diode 70 is on the order of tens of nanoseconds.

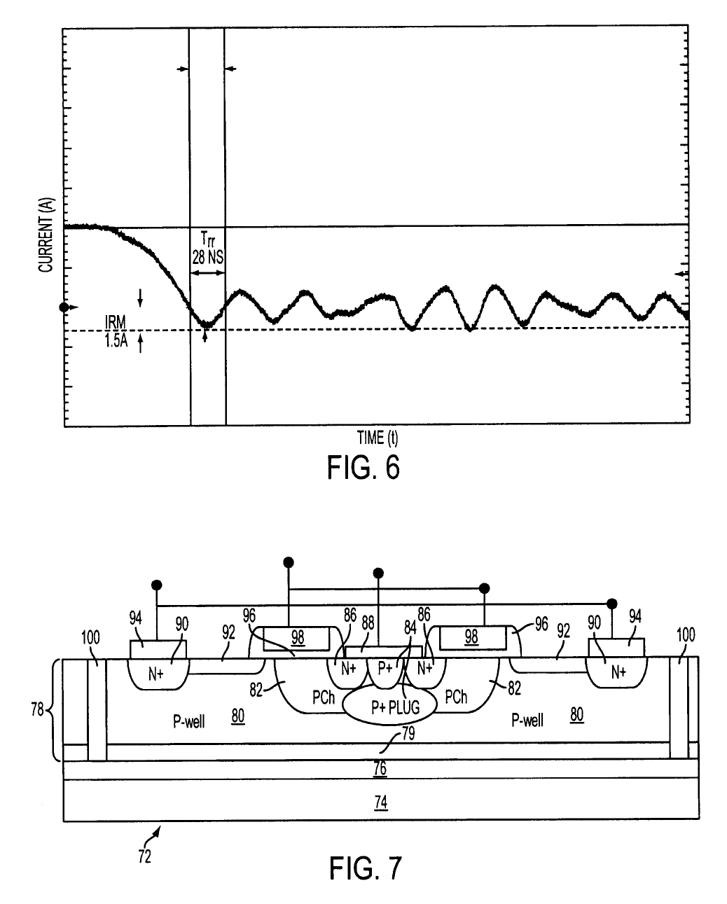

FIG. 6 illustrates a measured reverse recovery waveform for a lateral power MOSFET with a Schottky diode. Tᵣᵣ is approximately 28 ns. A small I_{RM} of approximately 1.5 A and the relatively short tᵣᵣ results from the small amount of charge stored within the body diode of the MOSFET.

Although the addition of Schottky diode 70 improves the efficiency of the converter circuit, a discrete Schottky diode would have certain drawbacks. The diode takes up valuable board space and increases circuit complexity. As a result, the maximum size for the MOSFET is reduced which similarly reduces RDSON for the entire package. In the case of external Schottky diodes, the package and board inductance between the MOSFET and the Schottky diode results in poor electrical coupling during switching. The poor electrical coupling limits the capacity of the Schottky diode to divert current from the body diode of the MOSFET.

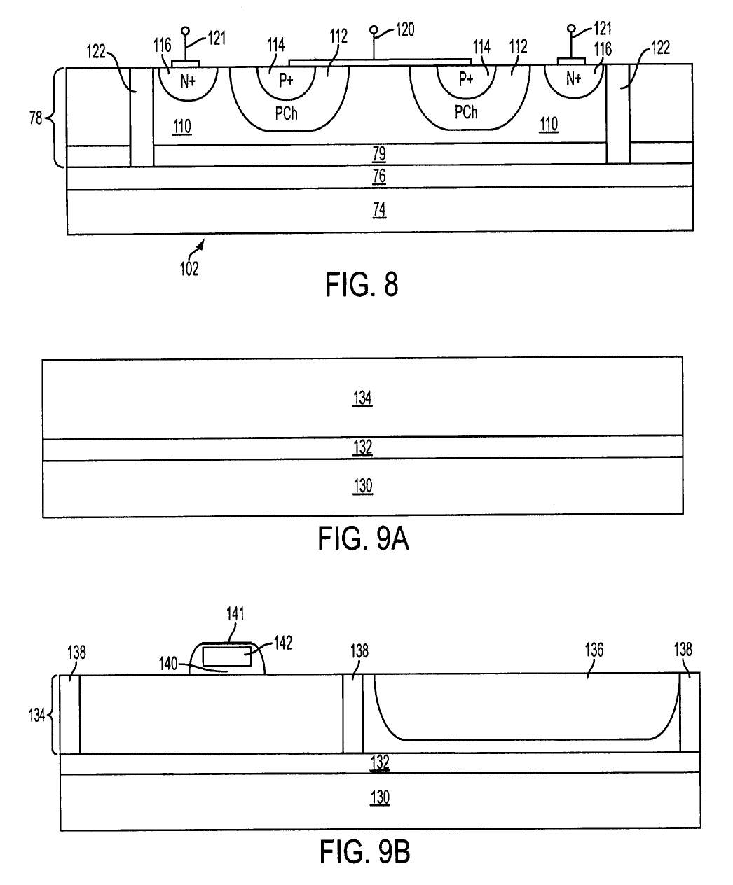

FIGS. 7 and 8 illustrate cross-sectional views of a lateral power MOSFET and integrated Schottky diode formed monolithically onto the same substrate. In one embodiment, both devices are formed over a silicon-on-insulator (SOI) substrate. A trench filled with silicon dioxide (SiO2) is formed within the substrate to electrically isolate the lateral power MOSFET and the Schottky diode. By isolating the MOSFET and the Schottky diode, a plurality of isolated lateral power MOSFETs and Schottky diodes may be formed over a common substrate. Metallization layers are used to couple each of the Schottky diodes to one or more of the lateral power MOSFETs. The metal layers can be formed using patterning with PVD, CVD, sputtering, electrolytic plating, electroless plating process, or other suitable metal deposition process. The metal layers can be one or more layers of Al, Cu, Sn, Ni, Au, Ag, or other suitable electrically conductive material. The structure may be used in all lateral power device structures that include MOSFETs and require fast reverse recovery.

FIG. 7 illustrates a cross-sectional view of lateral power MOSFET 72. Substrate 74 is made of P-type semiconductor material and provides structural support to the device. SiO2 layer 76 is formed over substrate 74 using CVD, PVD, or other suitable deposition process. SiO2 layer 76 provides electrical insulation between substrate 74 and the devices formed over substrate 74 above SiO2 layer 76. The insulation minimizes the parasitic device capacitance that would otherwise be generated by substrate 74.

A second P-type substrate 78 is bonded over SiO2 layer 76. In one example bonding process, a SiO2 layer 79 is formed over a surface of substrate 78. Substrate 78 is inverted and SiO2 layer 79 is bonded to SiO2 layer 76 to connect substrates 74 and 78. After bonding, substrate 78 may be planarized, depending upon the application. In one embodiment, the height of substrate 78 is reduced by grinding followed by chemical mechanical polishing (CMP).

P− well region 80 is formed within substrate 78. Body region 82 made with P-type material is formed within P− well region 80. P+ body 84 and N+ source region 86 are formed within P-type body region 82. In one embodiment, P+ body 84 includes a P+ plug region formed below N+ source region 86. Terminal 88 includes a conductive material and is deposited over N+ source region 86 and P+ body 84 to provide the source terminal of power MOSFET 72. N− drift region 92 and N+ drain region 90 are formed in the surface of P− well region 80. Terminal 94 is connected to N+ drain region 90 to form a drain terminal for MOSFET 72. Oxide layer 96 is formed over N+ source region 86, P-type body region 82, and N− drift region 92. Gate terminal 98 is formed over oxide layer 96. A trench is formed in substrate 78 using a laser drilling or another etching process and extends down to SiO2 layer 76. An insulative material such as SiO2 is deposited into the trench to form insulation trench 100. The isolation trench 100 surrounds the MOSFET device and electrically insulates the MOSFET from other devices formed over substrate 74.

FIG. 8 illustrates a cross-sectional view of Schottky diode 102 formed on substrates 74 and 78, as described in FIG. 7. N− well region 110 is formed within substrate 78. Anode regions 112 made with P-type material are formed within N− well region 110. P+ regions 114 are formed within P-type anode regions 112. N+ cathode regions 116 are formed within N− well region 110 using an implantation or other deposition process. Metal layer 120 is deposited over P+ regions 114 to form the metal anode of Schottky diode 102. Metal layer 120 can be formed using patterning with PVD, CVD, sputtering, electrolytic plating, electroless plating process, or other suitable metal deposition process. Metal layer 120 includes a conductive material such as titanium (Ti), Ni, platinum (Pt), and tungsten (W) and may be formed as a metal-silicide or metal-Si layer. Alternatively, metal layer 120 can be one or more layers of Al, Cu, Sn, Ni, Au, Ag, or other suitable electrically conductive material. Metal layer 121 is deposited over N+ cathode regions 116. Terminals 120 and 121 are connected to other devices formed over substrates 74 and 78, for example to interconnect Schottky diode 102 with other lateral power MOSFETs. A trench is formed in substrate 78 using a laser drilling or other etching process and extends down to SiO2 layer 76. An insulative material such as SiO2 is deposited into the trench to form insulation trench 122. The isolation trench 122 surrounds the Schottky diode and electrically insulates the diode from other structures formed in substrates 74 and 78.

By combining the MOSFET and the diode on a common monolithic substrate, the overall board space and component count for a device can be reduced, as well as simplifying the manufacturing process. Also, because the two devices are in close proximity, minimal metallization layers can be used to connect the lateral power MOSFET and the Schottky diode. The metallization layers provide a low resistance and low inductance connection mechanism between the two components allowing for efficient coupling of the Schottky diode to the MOSFET under fast switching conditions such as those found in synchronous buck DC-to-DC converters. Finally, multiple isolated later power MOSFETs with one or more coupled Schottky diodes can be monolithically integrated—again providing for flexible package and device design.

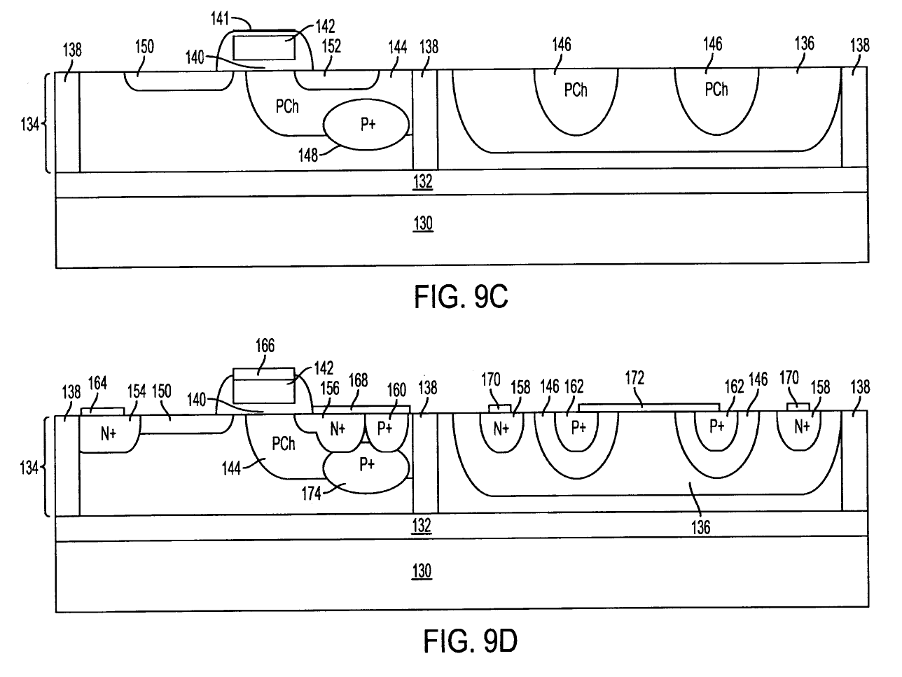

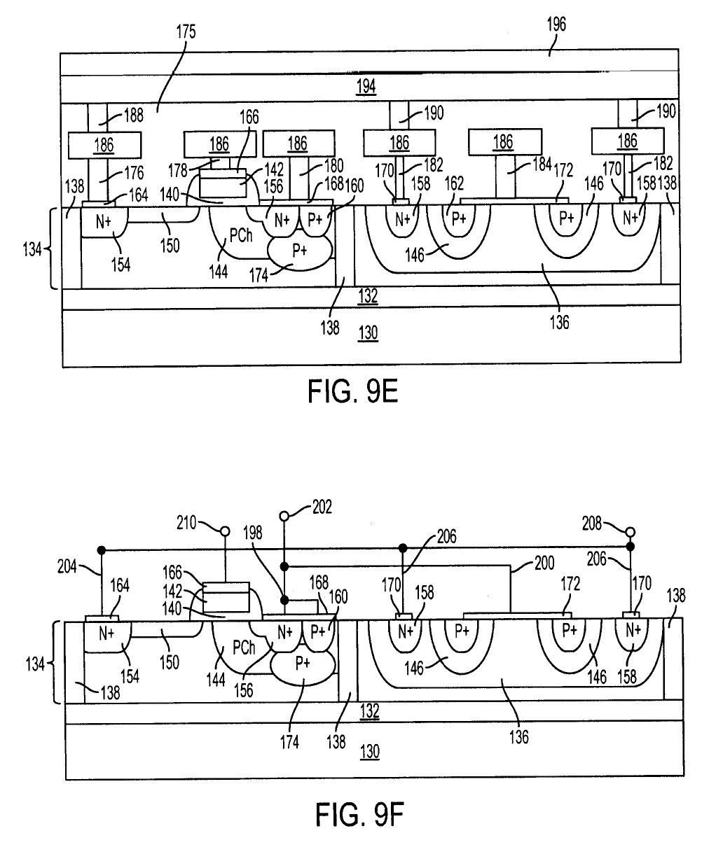

FIGS. 9A-9F illustrate further detail of fabricating the lateral power MOSFET and integrated Schottky diode described in FIGS. 7-8. As described below, the Schottky diode is formed in proximity to the MOSFET on the same monolithic substrate. In FIG. 9A, substrate 130 includes a P-type substrate material such as a doped Si semiconductor substrate. A layer of SiO2 is formed over a surface of substrate 130 using a CVD, PVD, thermal oxidation, or other deposition process. Another layer of SiO2 is formed over substrate 134. Substrate 134 is inverted and the two SiO2 layers are bonded together to form SiO2 layer 132. In one embodiment, after bonding, the thickness of SiO2 layer 132 is approximately 2 micrometers (μm). Substrate 134 may be thinned using CMP or other thinning process.

In FIG. 9B, N-well 136 is formed using photolithography and implantation. A trench is formed in substrate 134 using a laser drilling or other etching process and extends down to SiO2 layer 132. An insulator such as SiO2 is deposited into the trench to form insulation trench 138. Alternatively, isolation trench 138 can be formed by a thermal oxidation process. The isolation trench 138 provides electrical insulation to the devices formed within substrate 134. Gate oxide 140 is thermally grown over substrate 134 to form a gate junction of the MOSFET. Gate polycide 142 is formed over gate oxide 140 to form a gate terminal. Gate cap 141 includes an oxide layer and is deposited over gate polycide 142 using a high-temperature low-pressure deposition (HLD) process. In one embodiment, gate cap 141 includes tetraethvlorthosilicate (TEOS) and has a thickness of approximately 1500 angstroms (Å).

In FIG. 9C, a plurality of doped regions is formed within substrate 134 using photolithography and implantation processes. P-channel regions 144 and 146 are formed within substrate 134. P+ plug 148 is formed adjacent to and partially overlapping P-channel region 144. N-type LDD region 150 are formed partially beneath gate oxide 140. N-type LDD region 152 is formed within P-channel 144, partially beneath gate oxide 140.

In FIG. 9D, substrate 134 is further doped to form N+ regions 154, 156, and 158 are formed using a photolithography and implantation process. N+ region 154 forms a drain of the MOSFET; N+ region 156 forms a source of the MOSFET; N+ region 158 forms a cathode of the Schottky diode. P+ region 160 is formed within P-channel region 144. P+ region 162 is formed within P-channel regions 146. A conductive layer is deposited over substrate 134 and patterned and etched to form interconnect metal layers 164, 166, 168, 170, and 172. The interconnect metal layers 164-172 can be Ti, Ni, Pt, W, Au, Ag, metal- silicide, or metal-Si. The metal layer 172 forms the anode terminal of the Schottky diode. P+ plug 174 is formed beneath N+ region 156 and P+ region 160.

In FIG. 9E, an interconnect structure is formed over substrates 130 and 134. An interlayer dielectric material 175 is deposited over substrate 134. The dielectric material 175 is patterned and etched and conductive material such as W, Ti, Cu, Ag, Al, or Au is deposited into the etched portions to form vias 176, 178, 180, 182, and 184. Metal layer 186 is deposited over substrate 134 and electrically connected to vias 176, 178, 180, 182, and 184. Metal layer 186 can be formed using patterning with PVD, CVD, sputtering, electrolytic plating, electroless plating process, or other suitable metal deposition process. Metal layer 186 can be one or more layers of Al, Cu, Sn, Ni, Au, Ag, or other suitable electrically conductive material. Another layer of dielectric material 175 is deposited over metal layer 186 and then etched. Conductive material such as W, Cu, Au, Al, or Ag is deposited into the etched portions of the dielectric material 175 to form electrically isolated vias 188 and 190. Metal layer 194 is deposited over vias 188 and 190 in dielectric material 175. Metal layer 194 includes a conductive material such as Cu, Au, Al, Ti, or Ag and is patterned and etched. Passivation layer 196 is deposited or formed over metal layer 194 using PVD, CVD, printing, spin coating, spray coating, sintering, or thermal oxidation to provide physical support and electrical insulation to the device. The passivation layer 196 can be one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. A portion of passivation layer 196 can be removed by an etching process to expose portions of metal layer 194.

FIG. 9F illustrates an equivalent interconnect structure for forming a lateral power MOSFET with an integrated Schottky diode. Source terminal 198 of the MOSFET is connected to anode terminal 200 of the Schottky diode to form a combined source/anode terminal 202. Drain terminal 204 of the MOSFET is connected to cathode terminal 206 of the Schottky diode to form a combined drain/cathode terminal 208. Finally, gate terminal 210 is connected to gate interconnect pad 166.

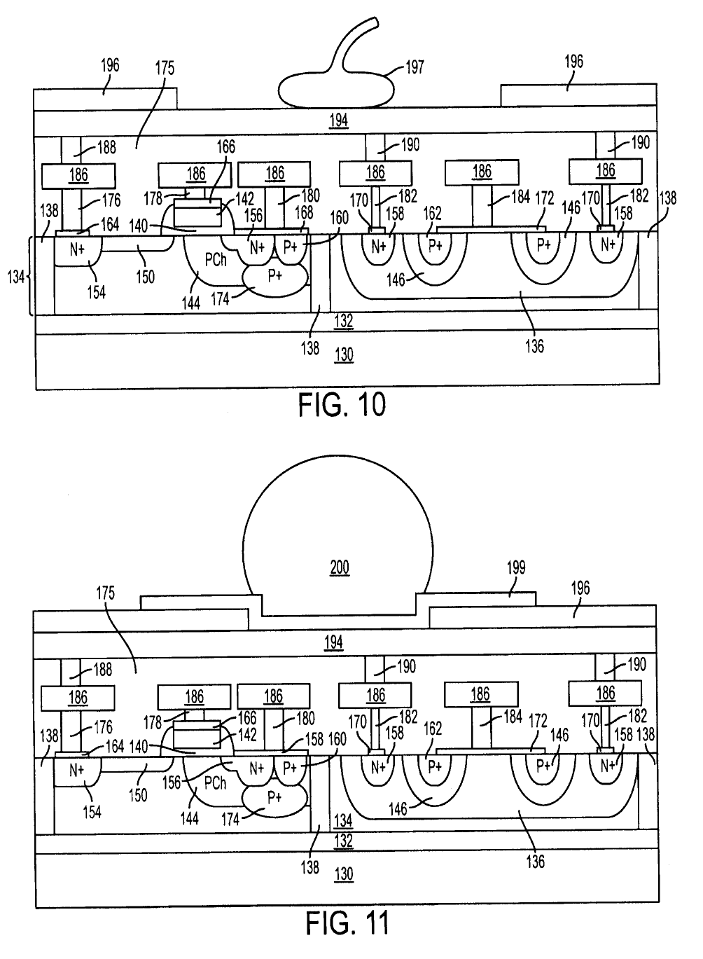

FIG. 10 illustrates a cross-sectional view of a lateral power MOSFET with integrated Schottky diode including etched passivation for a wirebond interconnect. The device is fabricated using the process described in FIGS. 7, 8, and 9A-9F. A portion of passivation layer 196 is removed by an etching process to expose portions of metal layer 194. A wire bond 197 is formed on the exposed portions of metal layer 194 to connect to the combined drain/cathode terminal 208 and further to interconnect the lateral power MOSFET and integrated Schottky diode to other system components. Wirebond 197 can be a thin wire of conductive material such as Al, Cu, Au, and Ag. A combination of heat and/or pressure may be used to bond the wire to metal layer 194.

FIG. 11 illustrates the lateral power MOSFET with integrated Schottky diode configured for a solder bump interconnection. Passivation layer 196 is etched or patterned to expose portions of metal layer 194 and to form an interconnect site. An optional under-bump metallization (UBM) 199 is formed over the exposed portions of metal layer 194. UBM 199 includes one or more layers of conductive materials including Ti, Cu, Al, Au, Ag, or nickel vanadium (NiV). UBM 199 is formed by any suitable process, including first etching a portion of metal layer 194 and then applying one or more metal layers using a vacuum deposition by evaporation or sputtering process or a chemical plating process. In one embodiment, UBM 199 can be a multi-metal stack with adhesion layer, barrier layer, and seed or wetting layer. The adhesion layer can be Ti, titanium nitride (TiN), titanium tungsten (TiW), Al, or chromium (Cr). The barrier layer is formed over the adhesion layer and can be made of Ni, nickel vanadium (NiV), platinum (Pt), palladium (Pd), TiW, or chromium copper (CrCu). The barrier layer inhibits the diffusion of Cu into the active area of the die. The seed layer can be Cu, Ni, NiV, Au, or Al. The seed layer is formed over the barrier layer. UBM 199 provides a low resistive interconnect, as well as a barrier to solder diffusion and seed layer for solder wettability.

An electrically conductive material is deposited over UBM 199 using an evaporation, electrolytic plating, electroless plating, ball drop, or screen printing process. The conductive material can be Al, Sn, Ni, Au, Ag, Pb, Bi, Cu, solder, and combinations thereof, with an optional flux material. For example, the conductive material can be eutectic Sn/Pb, high-lead solder, or lead-free solder. The conductive material is bonded to UBM 199 using a suitable attachment or bonding process. In one embodiment, the conductive material is reflowed by heating the material above its melting point to form spherical balls or bumps 200. In some applications, bumps 200 are reflowed a second time to improve electrical contact to UBM 199. The bumps can also be compression bonded to UBM 199. Bumps 200 represent one type of interconnect structure that can be formed over UBM 199. The interconnect structure can also be a stud bump, micro bump, or other electrical interconnect.

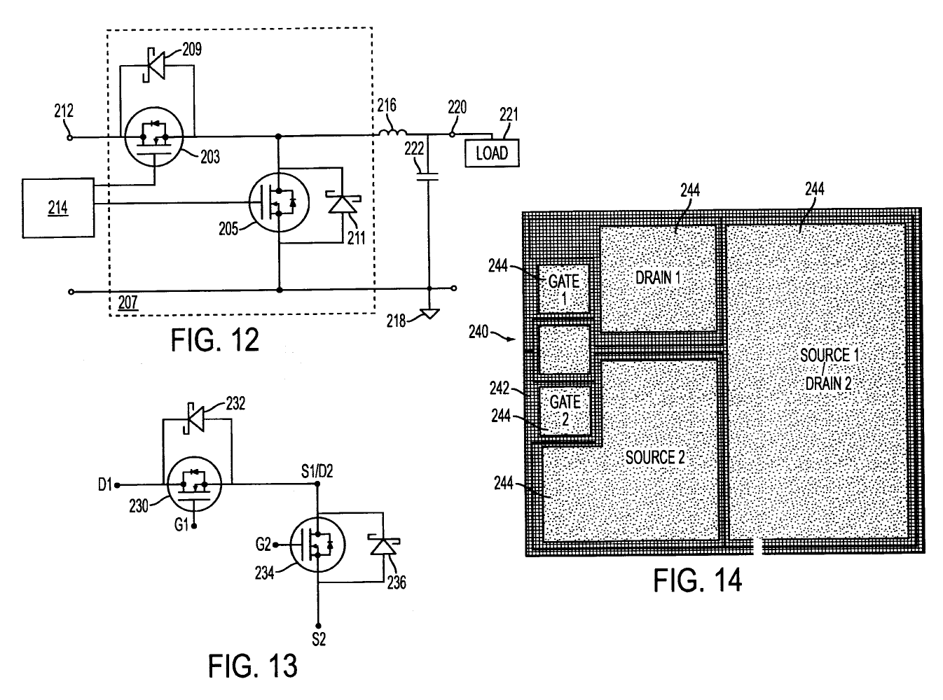

FIG. 12 illustrates a regulator circuit layout using a dual monolithic lateral power MOSFET with integrated Schottky diode. The regulator circuit operates as a step-down voltage regulator circuit. MOSFETs 203 and 205 are formed monolithically over substrate 207. MOSFET 203 is coupled to integrated Schottky diode 209 and MOSFET 205 is coupled to integrated Schottky diode 211, as described in FIGS. 7, 8, and 9A-9F. Terminal 212 is connected to the drain terminal of MOSFET 203 and the cathode of Schottky diode 209. PWM 214 is connected to the gate terminals of MOSFETs 203 and 205. PWM 214 controls the operation of MOSFETs 203 and 205 and includes logic for determining whether power should be supplied to the load or output 220 by terminal 212 or inductor 216. The source of MOSFET 203 is connected to the anode of Schottky diode 209, the drain terminal of MOSFET 205, the cathode of diode 211 and to a first terminal of inductor 216. A source of MOSFET 205 is connected to the anode of diode 211 and to a ground or low voltage connection 218. A second terminal of inductor 216 is connected to output 220, load 221, and a first terminal of capacitor 222. A second terminal of capacitor 222 is connected to ground or low voltage terminal 218.

During a first phase of operation of the regulator circuit, a voltage is supplied to the gate terminal of MOSFET 203. MOSFET 203 is turned on and energy flows from the drain terminal to its source terminal. MOSFET 205 is turned off. With MOSFET 203 turned on and MOSFET 205 turned off, energy is delivered from terminal 212, through inductor 216 to output terminal 220 and load 221. During this phase of operation, energy is accumulated within inductor 216.

In a second phase of operation, both MOSFETs 203 and 205 are turned off. The second phase is known as dead time and is the period of time during which the regulator circuit switches from the voltage at terminal 212 to inductor 216 as the energy supply for load 221. The voltage at the drain terminal of MOSFET 205 swings negative below the voltage at the source terminal until the body diode is forward biased. Current flows from the source to the drain of MOSFET 205 through inductor 216 to load 221. When the body diode of MOSFET 205 is forward biased, it stores charge in the body diode region that needs to be removed when the diode is reversed biased.

In a third phase of operation, MOSFET 203 remains switched off, and a voltage is supplied to the gate terminal of MOSFET 205 to activate the device. With MOSFET 205 turned on, the current stored within inductor 216 flows through MOSFET 205 and supplies energy to load 221.

In a fourth phase of operation, MOSFET 205 is turned off by reducing the gate to source voltage to a level below its threshold. During this time, the body diode of MOSFET 205 is forward biased and conducts current from the source to drain of MOSFET 205 through inductor 216 to load 221. The stored charge is accumulated in the body diode during forward bias. PWM 214 supplies a voltage to the gate to turn on MOSFET 203. The current through MOSFET 203 ramps up and the current through MOSFET 205 ramps down. The body diode of MOSFET 205 becomes reverse biased. Eventually, all of the current supplied to the inductor 216 is supplied from MOSFET 203. Schottky diode 211 operates to remove the stored charge in the body diode of MOSFET 205 to decrease tᵣᵣ and power loss of the MOSFET.

FIG. 13 illustrates an example configuration of dual monolithic SOI lateral MOSFETs with integrated Schottky diodes showing example device connection terminals. MOSFET 230 has integrated Schottky diode 232. MOSFET 234 has integrated Schottky diode 236. The drain terminal of MOSFET 230 is connected to the cathode of diode 232 and operates as a first drain input D1 for the dual integrated MOSFET device. The gate terminal of MOSFET 230 operates as a first gate G1 for the device. The source terminal of MOSFET 230 is connected to the anode of diode 232, cathode of diodes 236, and the drain terminal of MOSFET 234 to form a first source and second drain terminal S1/D2 for the device. The gate terminal of MOSFET 234 operates as a second gate G2 for the device. Finally, the source terminal of MOSFET 234 is connected to the anode of diode 236 and operates as a second source terminal S2 for the device.

FIG. 14 illustrates a top view of a substrate including dual monolithic lateral MOSFETs with integrated Schottky diodes, the substrate is configured for wire bond interconnection. In one embodiment, the integrated lateral power MOSFETs having integrated Schottky diodes of FIG. 13 are formed over a surface of substrate 240 using the present methods. Passivation film 242 (shown as 196 on FIG. 10) is formed over a top surface of substrate 240. Passivation film 242 is patterned or etched to expose portions of metal layer 244. The exposed portions of metal layer 244 include a plurality of interconnect sites for connecting to the circuit formed on substrate 240. Additional layers of conductive material may be deposited over the etched portions of encapsulant 242 to facilitate the formation of wire bond connections.

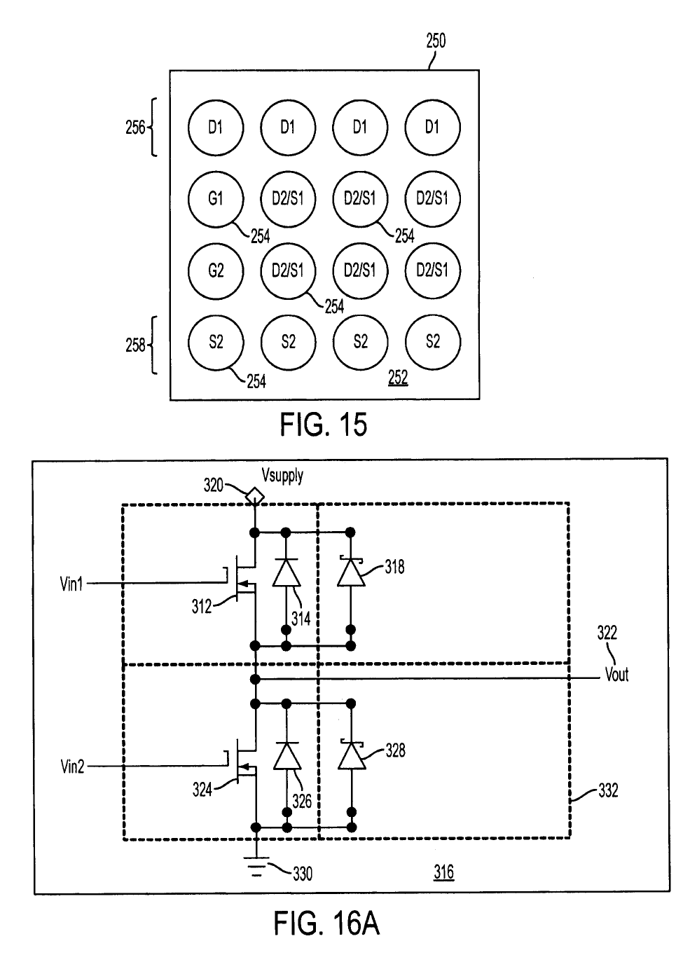

FIG. 15 illustrates a top view of a substrate including dual monolithic integrated lateral MOSFETs with integrated Schottky diodes, the substrate is configured for bump interconnection. In one embodiment, the integrated lateral power MOSFETs having integrated Schottky diodes of the circuit of FIG. 13 are formed over a surface of substrate 250 using the present methods. Die passivation film 252 (shown as 196 on FIG. 10) is formed over a top surface of substrate 250 and is patterned or etched to expose a plurality of bump interconnect sites 254. A UBM is formed over each bump interconnect site 254 to facilitate the formation of solder bumps. In one embodiment, the UBM includes a wetting layer, barrier layer, and adhesive layer. The top row 256 of interconnect sites 254 provides a first drain connection D1 for the circuit formed over substrate 250. The bottom row 258 of interconnect sites 256 provide a second source connection S2 for the circuit formed over substrate 250. A first and second gate connection G1 and G2 for the device are formed in a center of the left column of interconnect sites 254. Other interconnect sites 254 form a second drain and first source connection D2/S1 for the device. This configuration of interconnect sites 254 groups together connections sites providing similar functionality to simplify the process of forming connections between the interconnect sites 254 of the device and other system components. By grouping all of the drain, gate, source and combined drain and source connections together, other system components can be connected to the interconnect sites 254 using simplified interconnect routing. Furthermore, because the drain and source connections are provided by a plurality of interconnect sites 254, there is redundancy in the case that one of the bump connections fails. Although a single interconnect site 254 is provided for each of the gate terminals, the gate connection sites are formed within a row or column of the interconnect sites 254, not at a corner, and minimizes the likelihood of a connection failure.

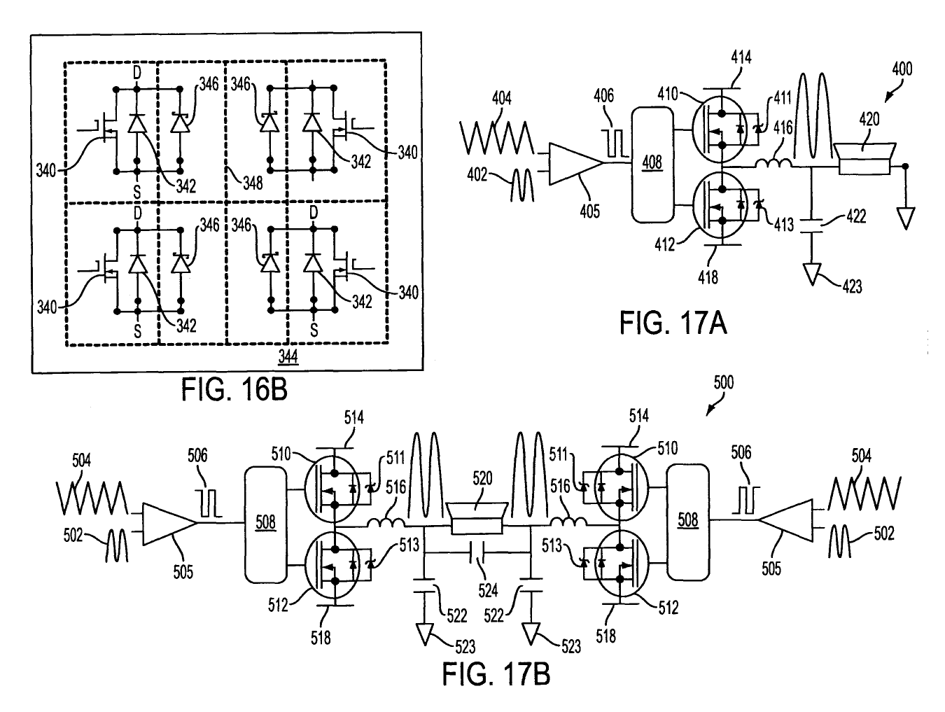

FIG. 16A illustrates an example substrate layout with dual lateral power MOSFETs having integrated Schottky diodes configured in a buck regulator topology. MOSFET 312 having body diode 314 is formed over substrate 316. Schottky diode 318 is formed over substrate 316 and electrically connected to MOSFET 312. Specifically, the drain of MOSFET 312 is connected to the cathode of diode 318 which are both, in turn, connected to voltage supply 320. The source of MOSFET 312 is connected to the anode of diode 318 which are both, in turn connected to output 322. MOSFET 324 having body diode 326 is formed over substrate 316. Schottky diode 328 is formed over substrate 316 and electrically connected to MOSFET 324. Specifically, the drain of MOSFET 324 is connected to the cathode of diode 328 which are both, in turn, connected to output 322. The source of MOSFET 324 is connected to the anode of diode 328 which are both, in turn connected to ground or low voltage 330. The insulation trench 332 is formed in substrate 316 to electrically isolate each of the devices.

FIG. 16B illustrates a substrate layout that includes multiple lateral power MOSFETs with integrated Schottky diodes. FIG. 16B shows an example layout of the MOSFET and Schottky diode devices on substrate 344. A plurality of MOSFETs 340 having body diodes 342 are formed over substrate 344. A plurality of Schottky diodes 346 is also formed over substrate 344. MOSFETs 340 are interconnected with Schottky diodes 346 using metallization layers or another electrical interconnection structure. The insulation trench 348 is formed in the substrate to electrically isolate each of the devices.

FIGS. 17A-17B illustrate audio amplifier circuits implemented using lateral power MOSFETs with integrated Schottky diodes. FIG. 17A illustrates a class D audio amplifier output stage 400 implemented as a half-bridge amplifier. An input audio signal 402 is combined with an input triangle wave 404 in amplifier 405 to form PWM signal 406 which is communicated to driver 408. Driver 408 controls the operation of MOSFETs 410 and 412 by controlling a voltage supplied to the gate terminals of MOSFETs 410 and 412. MOSFETs 410 and 412 include lateral power MOSFETs having integrated Schottky diodes 411 and 413, respectively. The drain terminal of MOSFET 410 is connected to voltage supply 414. The source terminal of MOSFET 410 is connected to a first terminal of inductor 416 and the drain terminal of MOSFET 412. The source terminal of MOSFET 412 is connected to ground or low voltage supply 418. A second terminal of inductor 416 is connected to a first terminal of capacitor 422 and speaker 420. A second terminal of capacitor 422 is connected to ground or low voltage source 423. Because MOSFETs 410 and 412 have a reduced reverse recovery time, amplifier 400 has a lower total harmonic distortion (THD). The reduced reverse recovery time will enable the circuit to operate at elevated switching speeds that will increase the sample rate, reduce THD, and improve fidelity. Furthermore, the frequency of input triangle wave 404 can be increased to a level above the amplitude-modulated (AM) band to provide additional fidelity and physical size improvements.

FIG. 17B illustrates a full bridge class D audio amplifier output stage 500. Amplifier 500 includes lateral power MOSFETs with integrated Schottky diodes. An input audio signal 502 is combined with input triangle waves 504 in amplifier 505 to form PWM signals 506 which are communicated to drivers 508. Drivers 508 control the operation of MOSFETs 510 and 512 by controlling a voltage supplied to the gate terminals of MOSFETs 510 and 512. MOSFETs 510 and 512 include lateral power MOSFETs having integrated Schottky diodes 511 and 513, respectively. The drain terminals of MOSFETs 510 are connected to voltage supplies 514. The source terminals of MOSFETs 510 are connected to first terminals of inductors 516 and the drain terminals of MOSFETs 512. The source terminals of MOSFETs 512 are connected to ground or low voltage supplies 518. Second terminals of inductors 516 are connected to first terminals of capacitors 522, capacitor 524, and speaker 520. Second terminals of capacitors 522 are connected to ground or low-voltage terminals 523. Because the MOSFETs have a reduced reverse recovery time, amplifier 500 has a lower THD. The reduced reverse recovery time will enable the circuit to operate at elevated switching speeds that will increase the sample rate, reduce THD, and improve fidelity. Furthermore, the frequency of input triangle waves 504 can be increased to a level above the AM band to provide additional fidelity and physical size improvements.

While one or more embodiments of the present invention have been illustrated in detail, the skilled artisan will appreciate that modifications and adaptations to those embodiments may be made without departing from the scope of the present invention as set forth in the following claims.

What is claimed:

1. A monolithic semiconductor device, comprising:
a first substrate;
an insulating layer formed over the first substrate;
a second substrate disposed over the insulating layer;
a power metal-oxide-semiconductor field-effect transistor (MOSFET) with body diode formed over the second substrate;
a first Schottky diode formed over the second substrate in proximity to the power MOSFET;
an insulation trench formed within the second substrate between the power MOSFET and first Schottky diode;
a first electrical connection formed between a source of the power MOSFET and an anode of the first Schottky diode; and
a second electrical connection formed between a drain of the power MOSFET and a cathode of the first Schottky diode.

2. The monolithic semiconductor device of claim 1, wherein the isolation trench surrounds the power MOSFET and first Schottky diode.

3. The monolithic semiconductor device of claim 1, further including:
a row of first interconnect sites coupled to the drain of the power MOSFET and cathode of the first Schottky diode;
a row of second interconnect sites coupled to the source of the power MOSFET and anode of the first Schottky diode; and
a third interconnect site coupled to a gate of the power MOSFET.

4. The monolithic semiconductor device of claim 3, wherein the first and second interconnect sites include a solder bump or wirebond.

5. The monolithic semiconductor device of claim 3, wherein the third interconnect site is disposed within the row of first interconnect site or within the row of second interconnect sites.

6. The monolithic semiconductor device of claim 1, wherein the first Schottky diode reduces charge build-up within the body diode and reverse recovery time of the power MOSFET.

7. The monolithic semiconductor device of claim 1, wherein the power MOSFET operates at higher switching speeds to increase audio sample rate.

8. A monolithic semiconductor device, comprising:
a first substrate;
a first power metal-oxide-semiconductor field-effect transistor (MOSFET) with body diode formed over the first substrate;
a first Schottky diode formed over the first substrate in proximity to the first power MOSFET;
a first electrical connection formed between a source of the first power MOSFET and an anode of the first Schottky diode; and
a second electrical connection formed between a drain of the first power MOSFET and a cathode of the first Schottky diode.

9. The monolithic semiconductor device of claim 8, further including:
a row of first interconnect sites coupled to the drain of the first power MOSFET and cathode of the first Schottky diode;
a row of second interconnect sites coupled to the source of the first power MOSFET and anode of the first Schottky diode; and
a third interconnect site coupled to a gate of the first power MOSFET.

10. The monolithic semiconductor device of claim 8, wherein the first Schottky diode reduces charge build-up within a body diode and reverse recovery time of the first power MOSFET.

11. The monolithic semiconductor device of claim 8, further including:
a second power MOSFET with body diode formed over the first substrate; and
a second Schottky diode formed over the first substrate in proximity to the second power MOSFET.

12. The monolithic semiconductor device of claim 8, further including an insulation trench formed within the first substrate between the first power MOSFET and first Schottky diode.

13. The monolithic semiconductor device of claim 12, wherein the isolation trench surrounds the first power MOSFET and first Schottky diode.

14. The monolithic semiconductor device of claim 8, further including:
an insulating layer formed over the first substrate; and
a second substrate disposed over the insulating layer.

15. A semiconductor device, comprising:
an electronic circuit; and
a switching device operating in response to the electronic circuit, the switching device including,
(a) a substrate,
(b) a power metal-oxide-semiconductor field-effect transistor (MOSFET) with body diode formed over the substrate,
(c) a Schottky diode formed over the substrate in proximity to the power MOSFET,
(d) a first electrical connection formed between a source of the power MOSFET and an anode of the Schottky diode, and
(e) a second electrical connection formed between a drain of the power MOSFET and a cathode of the Schottky diode.

16. The semiconductor device of claim 15, wherein the electronic circuit includes a pulse width modulator having an output coupled to a gate of the power MOSFET.

17. The semiconductor device of claim 15, wherein the electronic circuit includes an audio amplifier having an output coupled to a gate of the power MOSFET.

18. The semiconductor device of claim 15, further including:
a row of first interconnect sites coupled to the drain of the power MOSFET and cathode of the Schottky diode;
a row of second interconnect sites coupled to the source of the power MOSFET and anode of the Schottky diode; and
a third interconnect site coupled to a gate of the power MOSFET.

19. The semiconductor device of claim 15, further including an insulation trench formed within the substrate between the power MOSFET and Schottky diode.

20. A method of making a monolithic semiconductor device, comprising:
providing a first substrate;
forming a first power metal-oxide-semiconductor field-effect transistor (MOSFET) with body diode over the first substrate;
forming a first Schottky diode over the first substrate in proximity to the first power MOSFET;
forming a first electrical connection between a source of the first power MOSFET and an anode of the first Schottky diode; and
forming a second electrical connection between a drain of the first power MOSFET and a cathode of the first Schottky diode.

21. The method of claim 20, further including:
forming a row of first interconnect sites electrically connected to the drain of the first power MOSFET and cathode of the first Schottky diode;
forming a row of second interconnect sites electrically connected to the source of the first power MOSFET and anode of the first Schottky diode; and
forming a third interconnect site electrically connected to a gate of the first power MOSFET.

22. The method of claim 20, further including:
forming a second power MOSFET with body diode formed over the first substrate; and
forming a second Schottky diode formed over the first substrate in proximity to the second power MOSFET.

23. The method of claim 20, further including forming an insulation trench within the first substrate between the first power MOSFET and first Schottky diode.

24. The method of claim 23, wherein the isolation trench surrounds the first power MOSFET and first Schottky diode.

25. The method of claim 20, further including:
forming an insulating layer over the first substrate; and
disposing a second substrate over the insulating layer.
